(19) United States
(12) Patent Application Publication
(10) Pub. No.: US 2004/0250765 A1
(43) Pub. Date: Dec. 16, 2004

(54) Processing apparatus

(75) Inventors: Tadahiro Ishizaka, Nirasaki-shi (JP); Hiroshi Kannan, Tokyo (JP); Yasuhiko Kojima, Nirasaki-Shi (JP); Takashi Shigeoka, Nirasaki-Shi (JP); Yasuhiro Oshima, Nirasaki-Shi (JP); Kohei Kawamura, Nirasaki-Shi (JP)

Correspondence Address: CROWELL & MORING LLP, INTELLECTUAL PROPERTY GROUP, P.O. BOX 14300, WASHINGTON, DC, 20044-4300, US

(73) Assignee: Tokyo Electron Limited, Minato-Ku (JP)

(21) Appl. No.: 10/678,044

(22) Filed: Oct. 3, 2003

(30) Foreign Application Priority Data
Oct. 3, 2002 (JP) 2002-291578

(51) Int. Cl. C23C 16/00

(52) U.S. Cl. 118/715; 118/712; 156/345.29

(57) ABSTRACT

In a processing apparatus which performs a film deposition by alternately supplying a plurality of source gases, the source gases are prevented from reacting within an exhaust pipe so as to prevent the exhaust pipe from clogging due to a reaction by-product. A gas supply to a processing container is switched between a TiCl₄ supply system and a NH₃ supply system. Additionally, a gas exhaust from the processing container is switched between a TiCl₄ exhaust system and a NH₃ exhaust system. The gas exhaust is switched to the TiCl₄ exhaust system when the gas supply is switched to the TiCl₄ supply system, and the gas exhaust is switched to the NH₃ exhaust system when the gas supply is switched to the NH₃ supply system. The switching is performed by a stop valve provided to each of the supply system and the exhaust system.

### BACKGROUND OF THE INVENTION

1. Field of the Invention

The present invention relates to processing apparatuses and, more particularly, to a processing apparatus which performs a process by supplying a plurality of source gases to a substrate to be processed such as a semiconductor wafer.

2. Description of the Related Art

As a method of forming a high-quality thin film on a substrate by supplying process gases to the heated substrate, ALD (Atomic Layer Deposition) has attracted attention in recent years.

In a film deposition process by ALD, a plurality of kinds of source gases are supplied to a substrate so as to cause the source gasses react with each other on the substrate to form a very thin film of a reaction product. In this regard, the plurality of kinds of source gases are supplied on an individual kind basis by switching so that the source gases do not react with each other before reaching the substrate. That is, after supplying one kind of the source gas to the substrate so as to cause the source gas to be adsorbed, the gas that has not been adsorbed is completely exhausted and, then, different kind of source gas is supplied so as to react with the adsorbed gas on the substrate. This process is repeated several hundred times so as to cause a reaction product to grow up to be a thin film having a certain thickness.

In one time supply process of a source gas, only a small part of the source gas that contacts the surface of the substrate contributes to the reaction, and a large part of the source gas is exhausted from a process chamber while remaining unreacted. Then, immediately after one kind of source gas is exhausted, a next kind of source gas is supplied to the process chamber.

For example, in ALD, which supplies two kinds of source gases alternately, the following processes are performed.

1) Supply a first source gas into a process container, and cause the gas to be adsorbed onto a substrate.

2) Exhaust the first source gas remaining in the processing container.

3) Supply a second source gas into the process container, and cause the second source gas to react with the first source gas adsorbed on the substrate.

4) Exhaust the second source gas remaining in the process container and bi-products generated by the reaction.

The above processes 1)-4) are repeated so as to form a thin film of a predetermined film thickness on the substrate. In the above-mentioned process, the source gas, which was not adsorbed onto the substrate and did not contribute to the reaction, is exhausted from the process container as it is. Therefore, an amount of source gas exhausted as being unreacted in the film formation process by ALD is larger than that of a film formation process by usual CVD.

There are following technical references relevant to the invention of the present application.

1) Japanese Laid-Open Patent Application No. 3-28377

2) Japanese Laid-Open Patent Application No. 2001-214272

3) Pamphlet of International Publication 02/15243

In the above-mentioned film formation process by ALD, if an unreacted source gas with a low steam pressure is exhausted from the process container, the gas is liquefied or solidified within an exhaust pipe and may adhere onto an inner wall of the exhaust pipe. Therefore, an amount of substance which adhered to the inner wall of the exhaust pipe for a long time of use is increased, which may finally clog the exhaust pipe.

Moreover, since the source gases are supplied alternatively, the source gas adheres to the inner wall of the exhaust pipe may react with another source gas which is exhausted and flows from the process container in a subsequent process. Accordingly, the source gases react with each other in the exhaust pipe which may cause a reaction product adhering to the inner wall of the exhaust pipe, or a reaction bi-product may adhere to the inner wall of the exhaust pipe, and, thereby, it is possible that the exhaust pipe clogs for a long time of use.

FIG. 1 is an outline schematic diagram showing a source-gas supply and exhaust system of a conventional processing apparatus. The processing apparatus shown in FIG. 1 is constituted, for example, as an apparatus which performs a film formation process for producing a TiN film by causing two kinds of source gases, TiCl₄ and NH₃, react with each other on a substrate W. In this case, in order to supply separately the source gasses, TiCl₄ and NH₃, to the process container 1, a supply pipe 2 for TiCl₄ and a supply pipe 3 for NH₃ are separately provided. Additionally, a supply pipe 4 is separately provided for supplying N₂ gas as a carrier gas and an exhaust purge gas to the process container. The supply pipes 2, 3 and 4 is provided with mass-flow controllers (MFCS) 5, 6 and 7 and open-and-close valves 8, 9 and 10 so as to control an amount of gas flow, respectively. The source gases are supplied to the process container 1 alternatively by controlling suitably opening and closing of the open-and-close valves 8, 9 and 10.

The source gases supplied to the process container 1 are exhausted by a vacuum exhaust apparatus 11 through an exhaust pipe 12. A trap 13 is provided between the process container 1 and the vacuum exhaust apparatus 11 so as to trap a reaction product, a bi-product and unreacted source gases.

In the film formation process which produces a TiN film by causing two kinds of source gases, TiCl₄ and NH₃, to react with each other on a substrate, a temperature inside the process container is about 400° C., in which NH₄Cl, which is a reaction bi-product as indicated by the following chemical formulae, is produced.

6TiCl₄+8NH₃→6TiN+24HCl+N₂

HCl+NH₃→NH₄Cl

The produced NH₄Cl is a white powdery substance.

However, a temperature inside the exhaust pipe through which the source gas to be exhausted is below 150° C., and it is considered that a reaction indicated by the following chemical formula occurs under such a temperature.

TiCl₄+NH₃→TiCl₄·nNH₃(n=2, 4)

It is known that the reaction product TiCl₄·nNH₃ (n=2, 4) is a yellow powdery substance.

In experiments conducted by the inventors using a processing apparatus such as shown in FIG. 1, it was observed that a considerable amount of yellow powdery substance accumulates in the exhaust pipe 12 and the cold trap 13. It is assumed that the yellow powdery substance is the above-mentioned TiCl₄·nNH₃ (n=2, 4).

As mentioned above, in the processing apparatus which performs a film formation process by supplying a plurality of kinds of source gases alternatively, there was a problem in that a reaction product adheres and accumulates on an inner wall of an exhaust pipe due to reaction of source gasses with each other within the exhaust pipe, which clogs the exhaust pipe.

Moreover, in the process of repeating the step of exhausting source gases as mentioned above, unreacted source gases are exhausted in a large amount, and there was a problem in that an amount of consumption of source gases is large.

### SUMMARY OF THE INVENTION

It is a general object of the present invention to provide an improved and useful processing apparatus in which the above-mentioned problems are eliminated.

A more specific object of the present invention is to provide a processing apparatus, which performs film formation by supplying a plurality of source gases alternatively and which can prevent clogging of an exhaust pipe due to a reaction product by preventing the source gases from reacting with each other within the exhaust pipe.

Another object of the present invention is to provide a processing apparatus which can reusably collect source gases exhausted as being unreacted.

In order to achieve the above-mentioned object, there is provided according to the present invention a processing apparatus for performing a process by supplying alternately a first source gas and a second source gas to a processing substrate, the processing apparatus comprising: a processing container in which the processing substrate is placed; a first supply system for supplying the first source gas into the processing container; a second supply system for supplying the second source gas into the processing container; a first exhaust system for exhausting the first source gas from an inside of the processing container; a second exhaust system for exhausting the second source gas from an inside of the processing container; supply system switching means for switching a gas supply system connected to the processing container between the first supply system and the second supply system; exhaust system switching means for switching a gas exhaust system of the processing container between the first exhaust system and the second exhaust system; control means for controlling the supply system switching means and the exhaust system switching means so as to switch the gas exhaust system to the first exhaust system when the gas supply system is switched to the first supply system, and switch the gas exhaust system to the second exhaust system when the gas supply system is switched to the second supply system.

The processing apparatus according to the above-mentioned invention may further comprise: a trap provided in the first exhaust system so as to trap the first source gas; and a recovery pipe for returning the first source gas that is trapped by the trap to the first supply system. Additionally, the processing apparatus according to the above-mentioned invention may further comprise a trap provided in the second exhaust system so as to trap a reaction by-product produced by a reaction of the first source gas and the second source gas. Further, the processing apparatus according to the above-mentioned present invention may further comprise a third supply system for supplying an inert gas to the processing apparatus.

Additionally, in the processing apparatus according to the present invention, the supply system switching system may include a first supply system stop valve provided in the first supply system and a second supply system stop valve provided in the second supply system, and opening and closing of the first supply system stop valve and the second supply system stop valve may be controlled by the control means.

Additionally, in the processing apparatus according to the present invention, the exhaust system switching system may include a first exhaust system stop valve provided in the first exhaust system and a second exhaust system stop valve provided in the second exhaust system, and opening and closing of the first exhaust system stop valve and the second exhaust system stop valve may be controlled by the control means.

Further, in the processing apparatus according to the present invention, the supply system switching means may include a supply system three-way valve connectable to one of the first supply system and the second supply system; the exhaust system switching means may include an exhaust system three-way valve connectable to one of the first exhaust system and the second exhaust system; and the supply system three-way valve and the exhaust system three-way valve may be controlled by the control means.

Additionally, in the processing apparatus according to the present invention, the supply system three-way valve and the exhaust system three-way valve may be pneumatically operated valves, and a compressed air supplied to the pneumatically operated valves may be supplied by an air-switching valve to one of the supply system three-way valve and the exhaust system three-way valve.

Additionally, in the processing apparatus according to the present invention, the first source gas may be selected from a group consisting of TiCl₄, TiF₄, TiBr₄, TiI₄, Ti[N(C₂H₅CH₃)]₄, Ti[N(CH₃)₂]₄, Ti[N(C₂H₅)₂]₄, TaF₅, TaCl₅, TaBr₅, TaI₅, Ta(NC(CH₃)₃) (N(C₂H₅)₂)₃, Ta(N(CH₃)₂) (NC₅H₁₁) , Ta[N(C₂H₅)₂]₅, Ta[N(CH₃)₂]₅ and Ta(N(C₂H₅)₂)₃(N(C₂H₅)₂), and the second source gas may be selected from a group consisting of NH₃, N₂H₄, NH(CH₃)₂ and N₂H₃(CH₃), so as to deposit a TiN film or a TaN film on the processing substrate.

Additionally, in the processing apparatus according to the present invention, the first source gas may be selected from a group consisting of TiCl₄, TiF₄, TiBr₄, TiI₄, Ti[N(C₂H₅CH₃)]₄, Ti[N(CH₃)2]₄, Ti[N(C₂H₅)₂]₄, TaF₅, TaCl₅, TaBr₅, TaI₅ Ta(NC(CH₃)₃) (N(C₂H₅)₂)₃, Ta(N(CH₃)₂) (NC₅H₁₁), Ta[N(C₂H₅)₂]₅, Ta[N(CH₃)₂]₅ and Ta(N(C₂H₅)₂)₃(N(C₂H₅)₂), the second source gas may be selected from a group consisting of NH₃, N₂H₄, NH(CH₃)₂ and N₂H₃(CH₃), the inert gas may be selected from a group consisting of N₂, Ar and He, so as to deposit a TiN film or a TaN film on the processing substrate.

According to the above-mentioned invention, in the processing apparatus which performs a film deposition by alternately supplying a first source gas and a second source gas, only the first source gas flows to the first exhaust system and only the second source gas flows to the second exhaust system by switching between the first supply system and the second supply system and simultaneously switching between the first exhaust system and the second exhaust system. Therefore, the source gases are prevented from being mixed and reacting with each other within the exhaust pipe, which can prevent the exhaust pipe from clogging due to a reaction by-product. Moreover, since the source gas exhausted as being unreacted can be trapped in a high-purity state, the trapped source gases can be returned to the supply system for reuse, which can reduce an amount of consumption of the source gases.

Other objects, features and advantages of the present invention will become apparent from the following detailed descriptions when read in conjunction with the accompanying drawings.

### BRIEF DESCRIPTION OF THE DRAWINGS

FIG. 1 is an outline schematic diagram of a conventional processing apparatus;

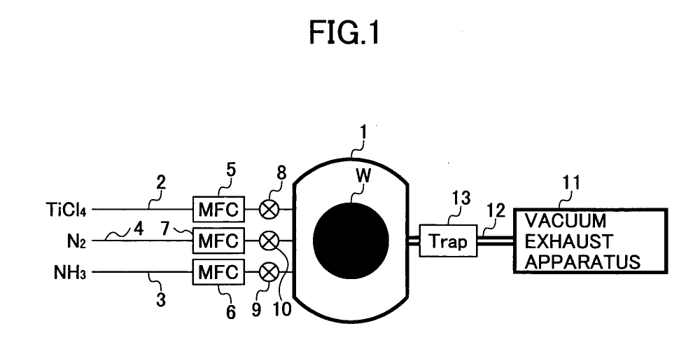

FIG. 2 is an outline schematic diagram of a processing apparatus according to the present invention;

FIG. 3 is an outline schematic diagram of a processing apparatus according to the present invention;

FIG. 4 is a schematic diagram of a processing apparatus according to a first embodiment of the present invention;

FIG. 5 is a diagram showing a state of each open-and-close valve of the processing apparatus in a TiCl₄ supply process;

FIG. 6 is a diagram showing a state of each open-and-close valve of the processing apparatus in a TiCl₄ exhaust process;

FIG. 7 is a diagram showing a state of each open-and-close valve of the processing apparatus in a NH₃ supply process.

FIG. 8 is a diagram showing a state of each open-and-close valve of the processing apparatus in a NH₃ exhaust process;

FIG. 9 is a schematic diagram of a processing apparatus according to a second embodiment of the present invention;

FIG. 10 is a diagram showing a state of each open-and-close valve of the processing apparatus in a TiCl₄ supply process;

FIG. 11 is a diagram showing a state of each open-and-close valve of the processing apparatus in a TiCl₄ exhaust process;

FIG. 12 is a diagram showing a state of each open-and-close valve of the processing apparatus in a NH₃ supply process.

FIG. 13 is a diagram showing a state of each open-and-close valve of the processing apparatus in a NH₃ exhaust process;

FIG. 14 is a diagram showing a structure which drives a three-way valve by air pressure; and

FIG. 15 is a structural diagram of an air switching valve.

### DETAILED DESCRIPTION OF THE PREFERRED EMBODIMENTS

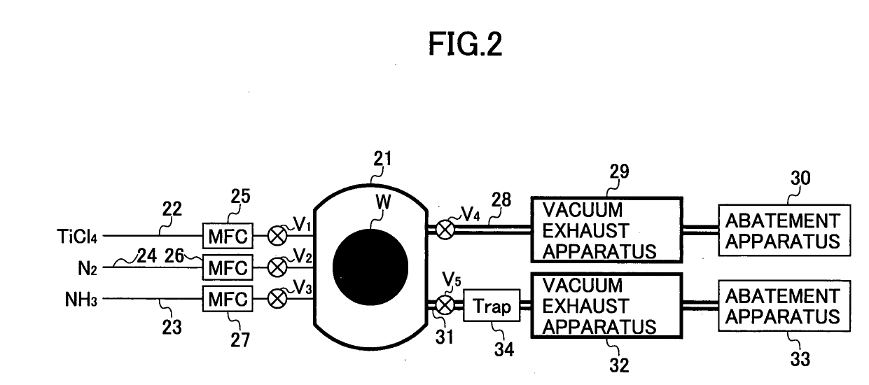

FIG. 2 is an outline schematic diagram showing an entire structure of a processing apparatus according to the present invention. The processing apparatus shown in FIG. 2 is constituted as an apparatus that performs a film deposition process for producing a TiN film by causing two kinds of source gas, TiCl₄ and NH₃, react with each other on a processing substrate (wafer) W. In this case, in order to supply separately TiCl₄ and NH₃, which are source gases, to a processing container 21, there are provided separately a supply pipe 22 for TiCl₄ and a supply pipe 23 for NH₃. Additionally, there is provided separately a supply pipe 24 for supplying N₂ gas, as a carrier gas and an exhaust purge gas, to the processing container 21. The supply pipe 22, 23 and 24 are provided with mass-flow controllers (MFCs) 25, 26 and 27 for controlling a gas flow rate and stop valves V1, V2 and V3, respectively. Source gases are supplied to the processing container 21 by controlling suitably opening and closing of the stop valves V1, V2 and V3. As mentioned above, the processing apparatus according to the present invention is provided with a first supply system that supplies TiCl₄ (first source gas), a second supply system that supplies NH₃ (second source gas) and a third supply system that supplies N₂ (inert gas).

Moreover, the processing apparatus according to the present invention is provided with two exhaust systems. That is, TiCl₄ supplied to the processing container 21 is suctioned by a vacuum exhaust apparatus 29 through an exhaust pipe 28, and is exhausted outside through an abatement apparatus 30 (the first exhaust system). On the other hand, NH₃ supplied to the processing container 21 is suctioned by a vacuum exhaust apparatus 32 through an exhaust pipe 31, which is different from the exhaust pipe 28, and is exhausted outside through an abatement apparatus 33 (the second exhaust system).

The exhaust pipe 28 for TiCl₄ is provided with a stop valve V4, and the exhaust pipe 31 for NH₃ is provided with a stop valve V5. Moreover, the stop valves V4 and V5 are controlled in relation to opening and closing of the stop valves V1, V2 and V3. Between the stop valve V5 and the vacuum exhaust apparatus 32 on the exhaust pipe 31, there is provided a trap 34 as a trap part trapping NH₄Cl, which is a by-product produced within the processing apparatus 21.

The processing apparatus shown in FIG. 2 produces a TiN film on the substrate W by performing the following processes.

1) Evacuate the processing container 21, carry the wafer W in the processing container 21, and heat the wafer W at about 400° C.

2) Supply TiCl₄ into the processing container 21.

3) Exhaust TiCl₄ in the processing container 21 through the exhaust pipe 28.

4) Supply NH₃ into the processing container 21.

5) Exhaust NH₃ in the processing container 21 through the exhaust pipe 31.

6) Repeat the processes of 2)-5) until the TiN film on the wafer W reaches a predetermined thickness.

7) End the film deposition process after the TiN film reaches the predetermined thickness, and carry the wafer W out of the processing container 21.

In order to perform the above-mentioned process, opening and closing of the stop valves V1-V5 are controlled as follows.

First, in process 1), the stop valves V1-V3 are closed and the stop valves V4 and V5 are opened and the vacuum exhaust apparatuses 29 and 32 are operated so as to evacuate the inside of the processing container 21.

Then, in process 2), the stop valve V1 is opened so as to supply TiCl₄ into the processing container 21, and a stop valve V4 is opened so as to exhaust the unreacted TiCl₄ in the processing container 21 by the vacuum exhaust apparatus 29 through the exhaust pipe 28. The stop valves V2, V3 and V5 are closed during process 2).

Next, in process 3), the stop valve V1 is closed and, instead, the stop valve V2 is opened. Thereby, N₂ gas is supplied into the processing container 21, which purges TiCl₄ in the processing container 21 and TiCl₄ is exhausted by the vacuum exhaust apparatus 29.

In process 4), the stop valve V2 is closed and, instead, the stop valve V3 is opened. Thereby, NH₃ is supplied into the processing container 21. At this time, the stop valve V4 for exhausting TiCl₄ is closed and, instead, the stop valve V5 for exhausting NH₃ is opened. Therefore, unreacted NH₃ and NH₄Cl which is a reaction by-product flow into the trap 34 by flowing through the exhaust pipe 31 for exhausting NH₃ without flowing into the exhaust pipe 28 for exhausting TiCl₄. The reaction by-product NH₄Cl is trapped by the trap 34, and NH₃ is suctioned by the vacuum exhaust apparatus 32 and released outside through the abatement apparatus 33.

Next, in process 5), the stop valve V3 is closed and, instead, the stop valve V2 is opened. Thereby, N₂ gas is supplied into the processing container 21, which purges NH₃ in the processing container 21 and NH₃ is exhausted by the vacuum exhaust apparatus 32.

After producing a TiN film having a desired thickness on the wafer W by repeating operations of the stop valves V1-V5 in the above-mentioned processes 2)-5), all the stop valves V1, V2 and V3 on the supply side are closed and the stop valves V4 and V5 on the exhaust side are opened so as to take the wafer W out of the processing container 21.

The above-mentioned operations of the stop valves are shown in a table below. It should be noted that ◯ indicates a state where the stop valve is open, and x indicates a state where the stop valve is closed.

| | |
|---|---|
| supply side | exhaust side |

| | V1 | V2 | V3 | V4 | V5 |
|---|---|---|---|---|---|
| 1) | X | X | X | ◯ | ◯ |
| 2) | ◯ | X | X | ◯ | X |
| 3) | X | ◯ | X | ◯ | X |
| 4) | X | X | ◯ | X | ◯ |
| 5) | X | ◯ | X | X | ◯ |
| 7) | X | X | X | ◯ | ◯ |

As mentioned above, since the processing apparatus according to the present invention has the exhaust system individually for each of a plurality of kinds of source gases and the exclusive exhaust pipe is provided to each of the source gases, the source gases are prevented from reacting with each other within the exhaust pipes. Thereby, an amount of substance deposited on the inner walls of the exhaust pipes is reduced, which prevents the exhaust pipes being clogged. The stop valves V1-V3 constitute a supply system switching means, and the stop valves V4 and V5 constitute an exhaust system switching means.

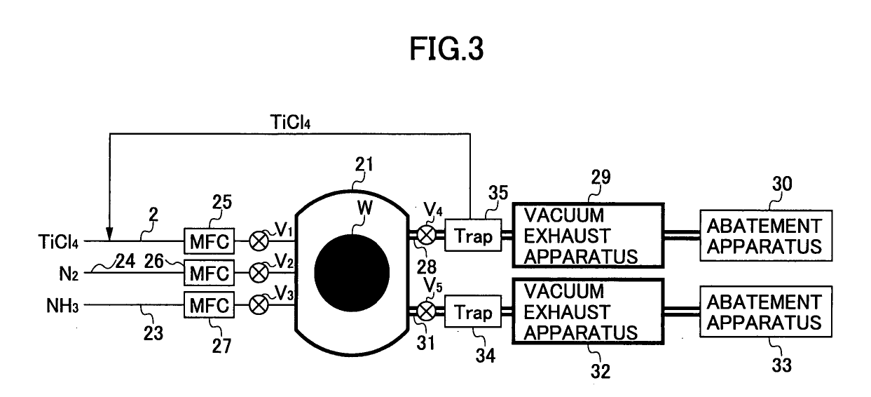

Moreover, in the processing apparatus according to the present invention shown in FIG. 2, a trap may be provided to the exhaust system of TiCl₄ as a trap part for trapping TiCl₄. FIG. 3 is an outline structure diagram of a processing apparatus which is provided with the trap of TiCl₄. In FIG. 3, parts that are the same as the parts shown in FIG. 2 are given the same reference numeral, and descriptions thereof will be omitted.

In the processing apparatus shown in FIG. 3, a trap 35 is provided between the stop valve V4 on the exhaust pipe 28 of TiCl₄ and the vacuum exhaust apparatus 29. The trap 35 consists of a cold trap, which liquefies and traps TiCl₄ having a low vapor pressure in the middle of the exhaust pipe 28. TiCl₄ trapped by the trap 35 is returned to the supply side, and is reused as a source gas.

Thus, in the processing apparatus shown in FIG. 3, since the exhaust system exclusive for TiCl₄ is provided, only TiCl₄ can be easily trapped by the cold trap. Since the trapped TiCl₄ is reused as a source gas, the consumption of the source gas can be reduced.

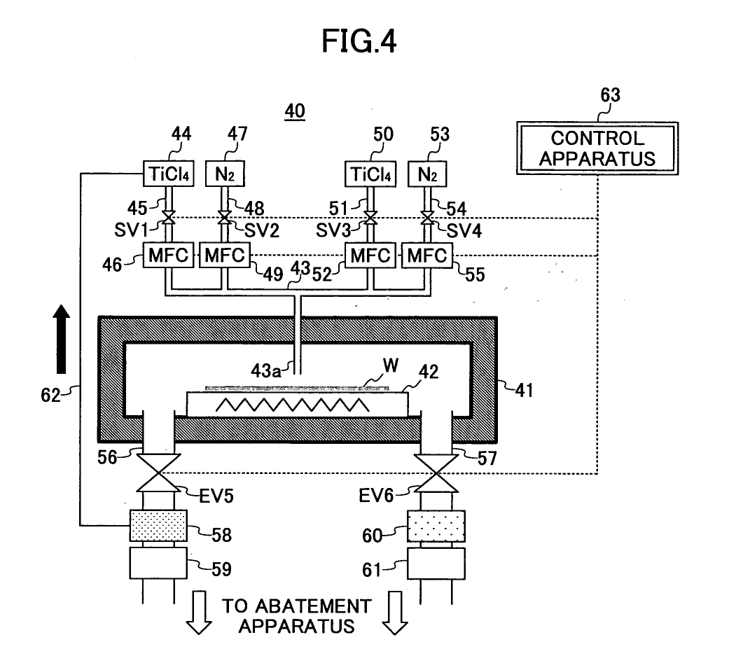

Next, a description will be given of a processing apparatus according to a first embodiment of the present invention. FIG. 4 is a diagram showing the processing apparatus 40 according to the first embodiment of the present invention. The processing apparatus 40 is constituted as an apparatus, which performs a film deposition process for producing a TiN film by causing two kinds of source gases, TiCl₄ and NH₃, react with each other on a substrate (wafer) W.

The processing apparatus 40 comprises a processing container 41 made of aluminum or stainless steel. If the processing container 41 is made of aluminum, an anodic oxide coating process (almite process) may be applied. In the processing container 41, a susceptor (placement stage) 42 equipped with a heater is arranged. The wafer W, which is a processing substrate, is placed on the susceptor 42, and subjected to the film deposition process. The processing container 41 has an airtight structure and the interior of the processing container 41 is maintained in a predetermined evacuated environment during the film deposition process.

In the present embodiment, supply pipes of source gases (TiCl₄, NH₃) and a purge gas (N₂) is integrated into a single common supply pipe 43 at a portion connected to the processing container 41. The end of the common supply pipe serves as a nozzle, and source gases are supplied into the processing container 41 through the nozzle. A showerhead may be provided instead of the nozzle.

A supply source 44 of TiCl₄ is connected to the common supply pipe 43 through a supply pipe 45. The supply pipe 45 is provided with a stop valve SV1 and a mass-flow controller 46. Moreover, a supply source 47 of N₂ as a purge gas is connected to the common supply pipe 43 through the supply pipe 48. The supply pipe 48 is provided with a stop valve SV2 and a mass-flow controller 49. Moreover, a supply source 50 of NH₃ is connected to the common supply pipe 43 through a supply pipe 51. The supply pipe 51 is provided with a stop valve SV3 and a mass-flow controller 52. Furthermore, a supply source 53 of N₂ as a purge gas is connected to the common supply pipe 43 through a supply pipe 54. The supply pipe 54 is provided with a stop valve SV4 and a mass-flow controller 55.

An exhaust pipe 56 for TiCl₄ and an exhaust pipe 57 for NH₃ are connected to the processing container 41. The exhaust pipe 56 is connected to a vacuum pump 59 through a stop valve EV5 and a trap 58. Moreover, the exhaust pipe 57 is connected to a vacuum pump 61 through a stop valve EV6 and a trap 60. Although dry pumps are used as the vacuum pumps 59 and 61, turbo molecular pumps may be provided on the upper stream of the traps 58 and 60.

The trap 58 is provided for trapping TiCl₄, and TiCl₄ trapped is returned to the supply source 44 of TiCl₄ through a recovery pipe 62, and is used again. In order to flow TiCl₄ of a gas state through the recovery pipe 62, a heater is wound around the recovery pipe 62 so as to heat the recovery pipe 62 at about 50 degrees C.-100 degrees C. so that TiCl₄ does not liquefy within the recovery pipe 62. On the other hand, the trap 60 is provided for trapping the reaction by-product NH₄Cl.

The above-mentioned stop valves SV1-SV4 and stop valves EV5 and EV6 are connected to a control apparatus 63, and opening and closing thereof are controlled by the control apparatus 63 as a control means. Moreover, the mass-flow controllers 46, 49, 52 and 55 are also controlled by the control apparatus 63 so that a flow rate of each gas is controlled.

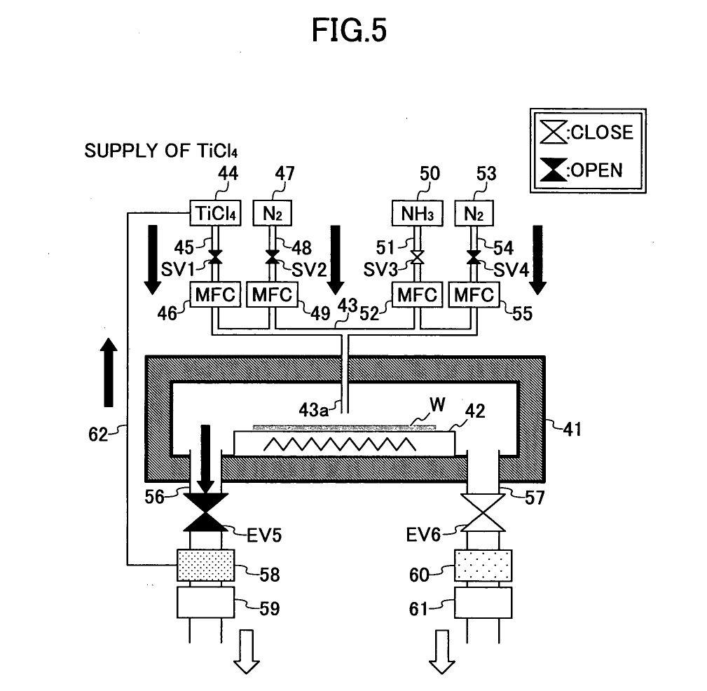

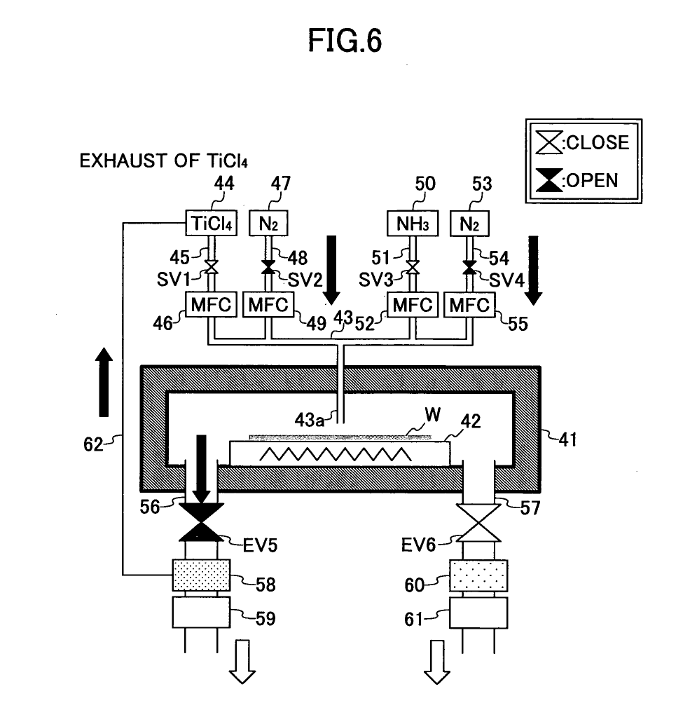

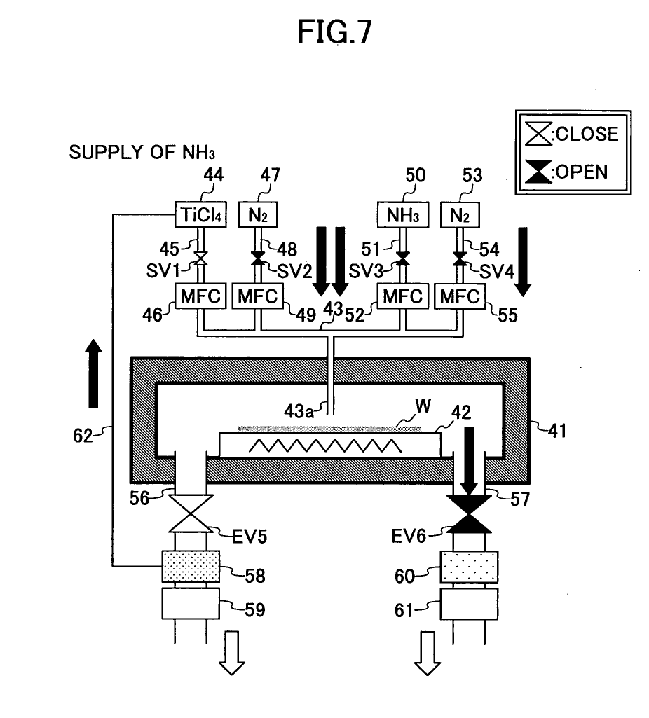

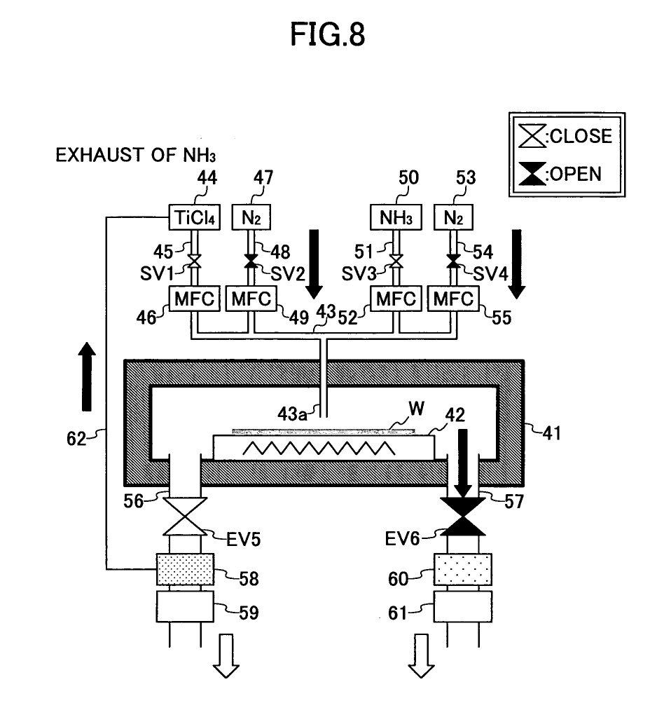

Next, a description will be given, with reference to FIG. 5 through FIG. 8, of a process operation in the processing apparatus of the above-mentioned structure. FIG. 5 is a schematic diagram showing a state of each stop valve of the processing apparatus 40 in a process of supplying TiCl₄, and FIG. 6 is a schematic diagram showing a state of each stop valve of the processing apparatus 40 in a process of exhausting TiCl₄. FIG. 7 is a schematic diagram showing a state each stop valve of the processing apparatus 40 in a process of supplying NH₃, and FIG. 8 is a schematic diagram showing a state of each stop valve of the processing apparatus 40 in a process of exhausting NH₃. It should be noted that, in the exhaust processes shown in FIG. 6 and FIG. 8, the source gasses are replaced by a N₂ purge.

First, in the TiCl₄ supply process shown in FIG. 5, the stop valve SV1 for supplying TiCl₄ and the stop valves SV2 and SV4 for supplying N₂ are opened, and the stop valve SV3 for supplying NH₃ is closed. Simultaneously, the stop valve EV5 for exhausting TiCl₄ is opened, and the stop valve EV6 for exhausting NH₃ is closed.

Therefore, the source gas TiCl₄ and the carrier gas N₂ are supplied into the processing container 41 from each of the supply sources 44, 47 and 53. A flow rate of TiCl₄ is controlled by the mass-flow controller 46 to be set to 30 sccm. Moreover, a flow rate of N₂ from the N₂ supply sources 47 and 53 is controlled by the mass-flow controllers 49 and 55 to be set to 100 sccm, respectively. Since the stop valve SV3 for supplying NH₃ is closed, NH₃ is not supplied to a processing container.

Although a part of TiCl₄ supplied into the processing container 41 is adsorbed onto the surface of the wafer W, a large part of TiCl₄ flows into the exhaust pipe 56 for exhausting TiCl₄ together with the carrier gas N₂. Since the stop valve EV6 provided to the exhaust pipe 57 for exhausting NH₃ is closed, TiCl₄ does not flow into the exhaust pipe 57 for exhausting NH₃.

TiCl₄ flowing into the exhaust pipe 56 is trapped by the trap 58, and is returned to the TiCl₄ supply source 44 through the recovery pipe 62. N₂ flowing into the exhaust pipe 56 is exhausted outside by the vacuum pump 59.

Thus, in the present embodiment, since only TiCl₄ and N₂ flow into the exhaust pipe 56, TiCl₄ can be easily trapped in a high-purity state and is returned to the TiCl₄ supply source 44 and reused. Thereby, an amount of consumption of TiCl₄ can be reduced.

After the supply process of TiCl₄ is ended, the exhaust process of TiCl₄ shown in FIG. 6 is performed next. In the present embodiment, the exhaust of TiCl₄ is performed by purging TiCl₄ by supplying only N₂ into the processing container 41. That is, in the exhaust process of TiCl₄, the stop valve SV1 for supplying TiCl₄ is closed, and other stop valves are maintained at an unchanged state. Therefore, only N₂ is supplied into the processing container 41, and TiCl₄ remaining in the processing container 41 is purged by N₂ from inside the processing container 41 to the exhaust pipe 56.

After the exhaust process of TiCl₄ is ended, the supply process of NH₃ shown in FIG. 7 is performed next. At the supply process of NH₃, the stop valve SV3 for supplying NH₃ and the stop valves SV2 and SV4 for supplying N₂ are opened, and the stop valve SV1 for supplying TiCl₄ is closed. Simultaneously, the stop valve EV5 for exhausting TiCl₄ is closed, and the stop valve EV6 for exhausting NH₃ is opened.

Therefore, the source gas NH₃ and the carrier gas N₂ are supplied into the processing container 41 from each supply sources 50, 47 and 53. A flow rate of NH₃ is controlled by the mass-flow controller 52 to be set to 100 sccm. Moreover, a flow rate of N₂ from N₂ supply sources 47 and 53 is controlled by the mass-flow controllers 49 and 55 to be set to 100 sccm, respectively. Since the stop valve SV1 for supplying TiCl₄ is closed, TiCl₄ is not supplied to the processing container 41.

Although a part of NH₃ supplied into the processing container 41 reacts with TiCl₄ adsorbed on the surface of the wafer W, a large part of NH₃ flows into the exhaust pipe 57 for exhausting NH₃ together with carrier gas N₂. Since the stop valve EV5 provided to the exhaust pipe 56 for exhausting TiCl₄ is closed, NH₃ does not flow into the exhaust pipe 56 for exhausting TiCl₄.

NH₃ and N₂ which flowing into the exhaust pipe 57 are exhausted outside by the vacuum pump 61. Moreover, in the supply process of NH₃, the reaction by-product NH₄Cl when NH₃ and TiCl₄ react with each other is generated inside the processing container 41. Therefore, the reaction by-product NH₄Cl also flows into the exhaust pipe EV6. Thus, in the present embodiment, NH₄Cl is trapped by the trap 60 so as to prevent NH₄Cl from flowing into the vacuum pump 61.

After the supply process of NH₃ is ended, the exhaust process of NH₃ shown in FIG. 8 is performed next. In the present embodiment, the exhaust of NH₃ is performed by purging NH₃ by supplying only N₂ into the processing container 41. That is, in the exhaust process of NH₃, the stop valve SV3 for supplying NH₃ is closed, and other stop valves are maintained in an unchanged state. Therefore, only N₂ is supplied into the processing container 41, and NH₃ remaining inside the processing container 41 is purged by N₂ from inside the processing container 41 to the exhaust pipe 57.

The above-mentioned processes of FIG. 5 through FIG. 8 are repeated until the TiN film deposited on the wafer W has a predetermined thickness. As mentioned above, the opening and closing operations of the stop valves SV1-SV4 and EV6 and EV7 are controlled by the control apparatus 63.

It should be noted that, in the above-mentioned exhaust process of TiCl₄ and exhaust process of NH₃, although the source gases are replaced by the N₂ purge, the exhaust of the source gases can also be performed by vacuuming. In this case, although the supply process of TiCl₄ and the supply process of NH₃ are the same as the processes shown in FIG. 5 and FIG. 7 and the same operations of the stop valves are performed, the exhaust process of TiCl₄ and the exhaust process of NH₃ differ from the processes shown in FIG. 6 and FIG. 8. That is, in order to exhaust source gases by vacuuming, the stop valves SV2 and SV4 for supplying N₂ are closed in the exhaust process of TiCl₄ and the exhaust process of NH₃ so as to stop the supply of gases to the processing container 41. Thereby, the source gasses are exhausted from inside the processing container 41 by evacuating the processing container 41 by the vacuum pump 59 or 61 until a predetermined vacuum pressure is reached.

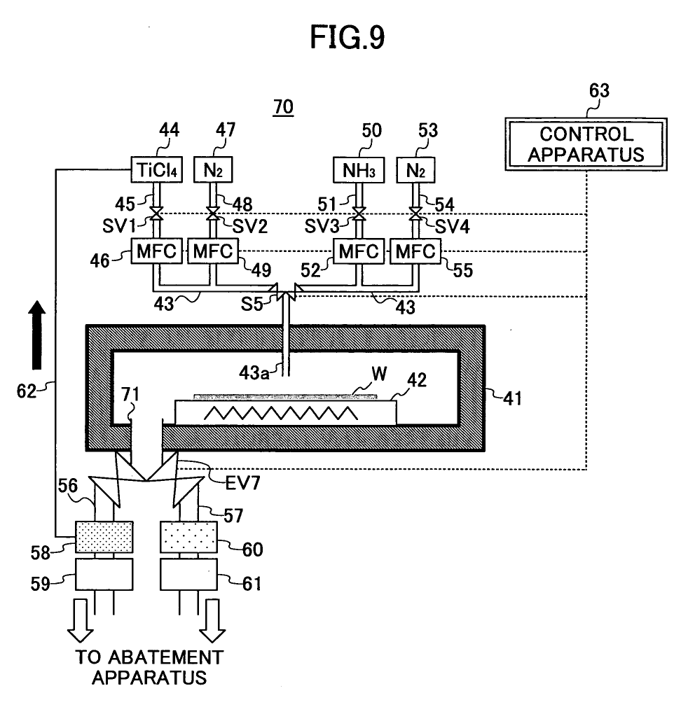

Next, a description will be given, with reference to FIG. 9, of a processing apparatus according to a second embodiment of the present invention. FIG. 9 is an outline schematic diagram showing an entire structure of the processing apparatus 70 according to the second embodiment of the present invention. In FIG. 9, parts that are the same as the parts shown in FIG. 4 are given the same reference numerals, and descriptions thereof will be omitted.

Although the processing apparatus 70 shown in FIG. 9 has a basic structure the same as the processing apparatus 40 shown in FIG. 4 except that a three-way valve SV5 is provided to the common supply pipe 43 and a common exhaust pipe 71 and the three-way valve EV7 are provided on the exhaust side. That is, in the present embodiment, the three-way valve is provided on both the supply side and the exhaust side so as to switch the supply system and the exhaust system simultaneously.

The three-way valve SV5 is provided in a branch portion where a nozzle 43a extends from the common supply pipe 43. The three-way valve SV5 achieves a function to switch the source gas supply system connected to the processing container 41 between the supply system of TiCl₄ and the supply system of NH₃. On the other hand, the three-way valve EV7 achieves a function to switch the exhaust system connected to the common exhaust pipe 71 between the exhaust system of TiCl₄ and the exhaust system of NH₃.

The stop valves SV1-SV4 and the there-way valve SV5 on the supply side and the three-way valve EV6 on the exhaust side are controlled by the control apparatus 63.

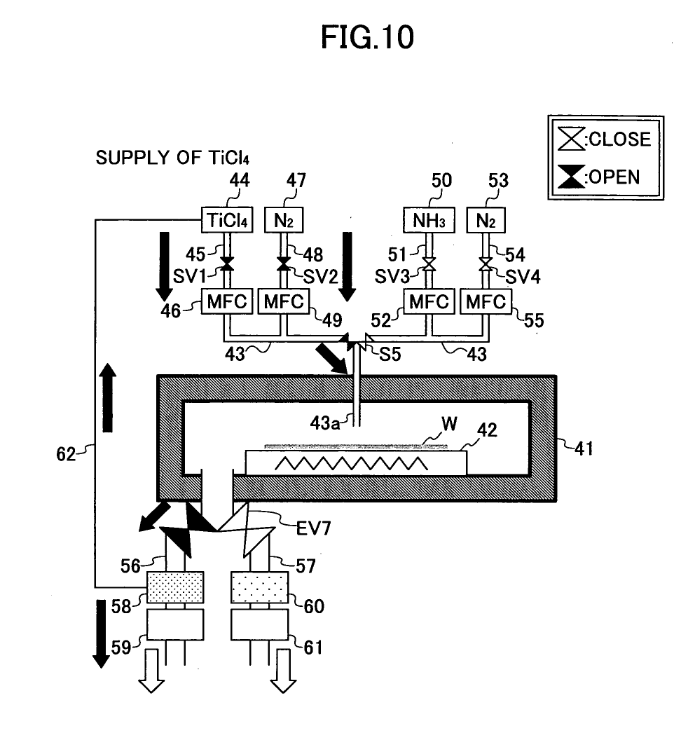

In the supply process of TiCl₄ shown in FIG. 10, the stop valves SV1 and SV2 on the TiCl₄ side are opened, and the stop valves SV3 and SV4 on the NH₃ side are closed. Then, the three-way valve SV5 is switched so that the supply system on the TiCl₄ side is connected to the nozzle 43a. Simultaneously, the three-way valve EV7 on the exhaust side is switched so as to be connected to the exhaust pipe 56 for TiCl₄. Thereby, TiCl₄ and N₂ supplied into the processing container 41 flow into only the exhaust pipe 56 for TiCl₄, and do not flow into the exhaust pipe 57 for NH₃.

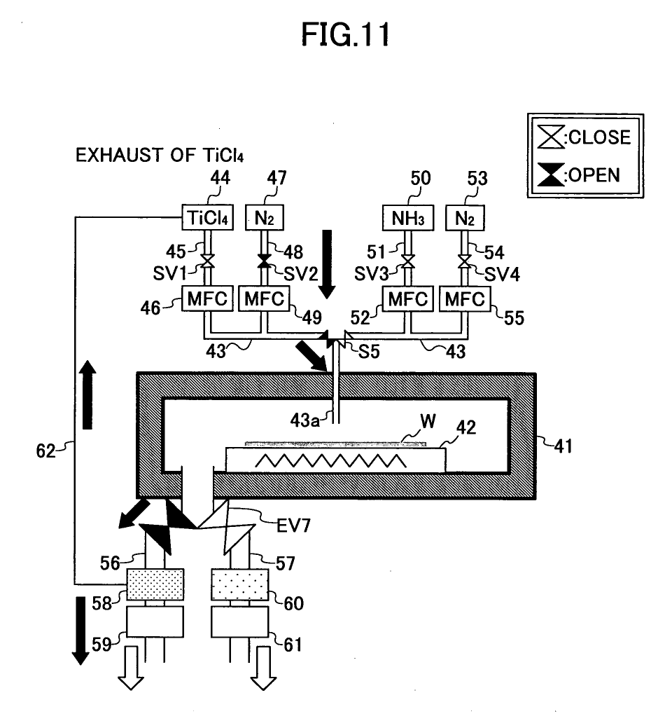

In the exhaust process of TiCl₄ shown in FIG. 11, the stop valve SV1 on the TiCl₄ side is closed, and the stop valve SV2 is maintained opened. The stop valves SV3 and SV4 on the NH₃ side are maintained closed. Moreover, the three-way valve SV5 is also maintained switched to the supply system on the TiCl₄ side. Moreover, the three-way valve EV7 on the exhaust side is also maintained switched to be connected to the exhaust pipe 56 for TiCl₄. Thereby, only N₂ is supplied to the processing container 41, and TiCl₄ remaining in the processing container 41 flows into the exhaust pipe 56 for TiCl₄ and is exhausted.

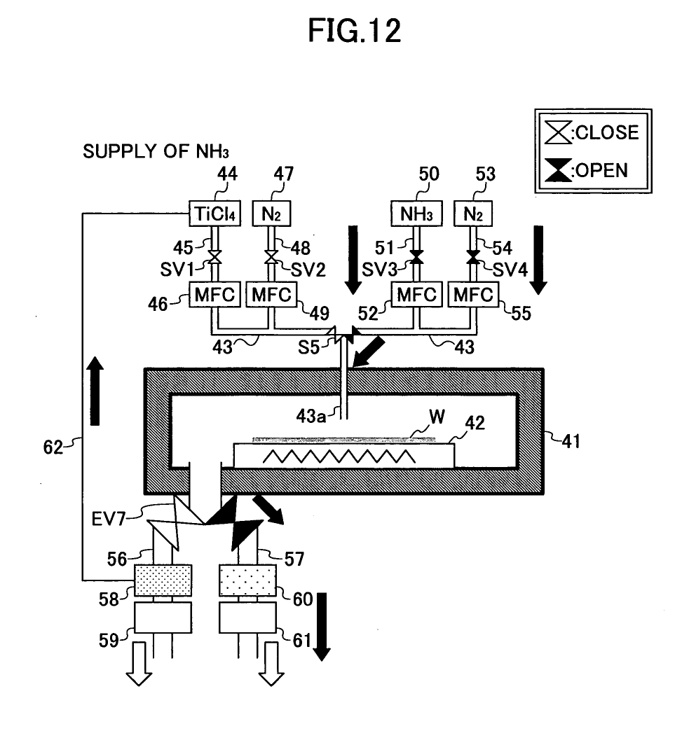

Then, in the supply process of NH₃ shown in FIG. 12, the stop valves SV1 and SV2 on the TiCl₄ side are closed, and the stop valves SV3 and SV4 on the NH₃ side are opened. The three-way valve SV5 is switched so that the supply system on NH₃ side is connected to the nozzle 43a. Simultaneously, the three-way valve EV7 on the exhaust side is switched so as to be connected to the exhaust pipe 57 for NH₃. Thereby, NH₃ and N₂ supplied into the processing container 41 flow into only the exhaust pipe 57 for NH₃, and do not flow into the exhaust pipe 56 for TiCl₄.

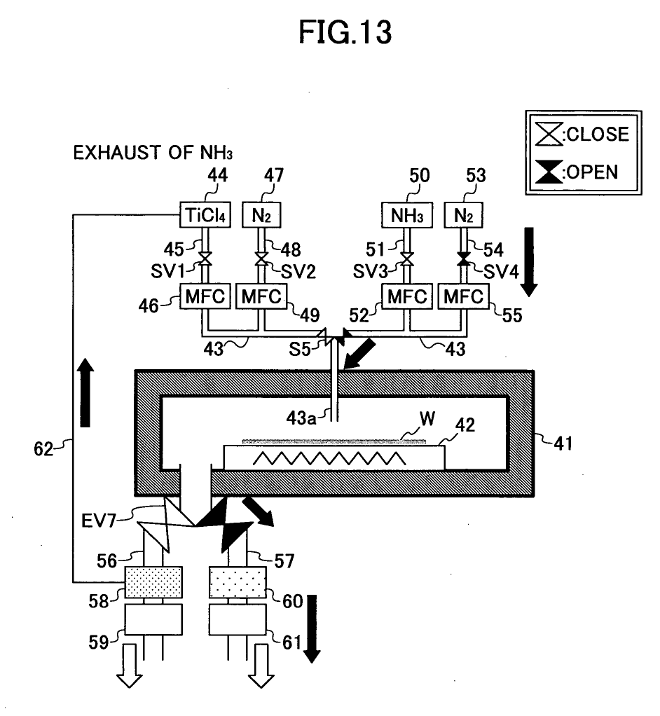

In the exhaust process of NH₃ shown in FIG. 13, the stop valve SV3 on the NH₃ side is closed, and the stop valve SV4 is maintained opened. The stop valves SV1 and SV2 on the TiCl₄ side are maintained closed. Moreover, the three-way valve SV5 is also maintained switched to the supply system side of the NH₃ side. Moreover, the three-way valve EV7 on the exhaust side is also maintained switched to be connected to the exhaust pipe 57 for NH₃. Thereby, only N₂ is supplied to the processing container 41, and NH₃ remaining in the processing container 41 flows into the exhaust pipe 57 for NH₃, and is exhausted.

As mentioned above, in the present embodiment, since the three-way valve SV5 is located in a part of the supply side close to the processing container 41a and the three-way valve EV7 is located in a part of the exhaust side close to the processing container 41, parts in which there is a possibility of contacting and reacting the source gases, TiCl₄ and NH₃, with each other are only inside the processing container 41 and the common exhaust pipe 71. Thereby, the reaction of source gases outside the processing container 41 can be prevented effectively.

It should be noted that, also in the present embodiment, the exhaust process can be performed not by the N₂ purge but vacuuming like the above-mentioned first embodiment.

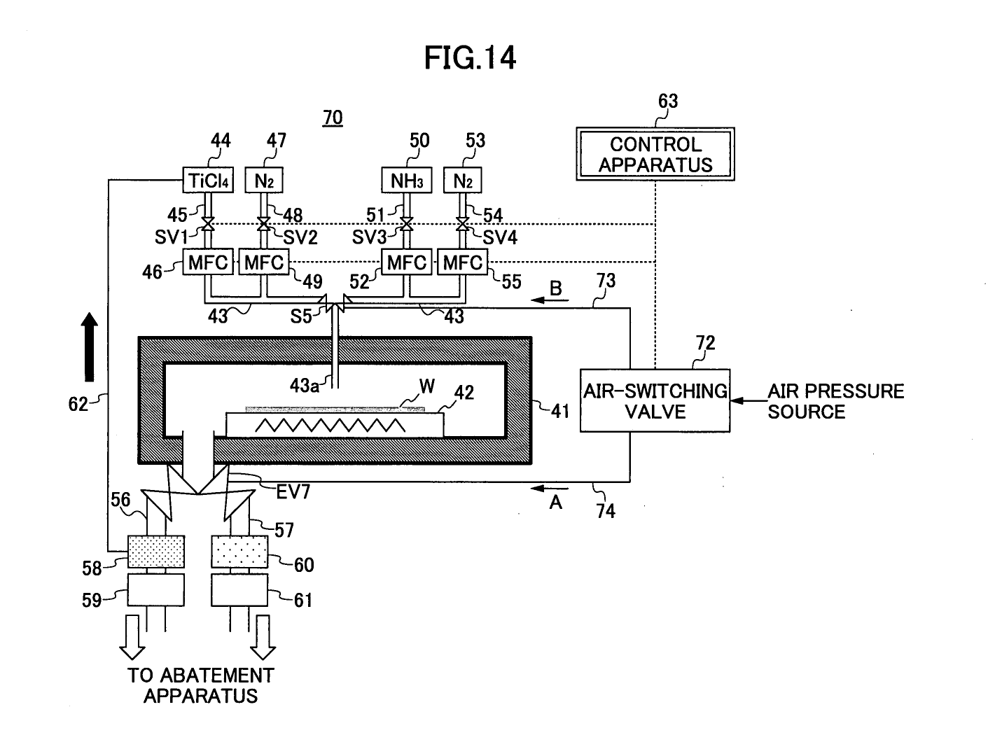

FIG. 14 is a diagram showing an arrangement of performing switching operations of the three-way valve SV5 and the three-way valve EV7 by air pressure in the processing apparatus 70 shown in FIG. 9. In FIG. 14, the three-way valve SV5 and the three-way valve EV7 are pneumatically driven valves, and three-way valve SV5 and the three-way valve EV7 are operated in synchronization with each other by supplying air pressure by an air-switching valve 72.

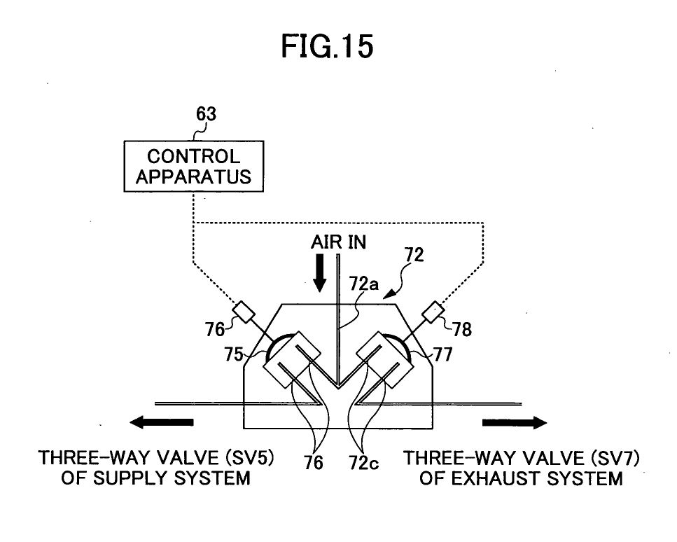

FIG. 15 is an illustration showing a structure of the air-switching valve 72. A compressed air is supplied from an air pressure source to the air-switching valve. A passage 72a of a compressed air branches into two passages 72b and 72c within the air switching valve 72, one being connected to an air passage 73 connected to the three-way valve SV5 of the supply system, and the other being connected to an air passage 74 connected to the three-way valve EV7 of the exhaust system.

A diaphragm 75 is provided in the middle of the passage 72b in the air-switching valve 72, and the diaphragm passage 72b can be opened and closed by driving the diaphragm 75. The diaphragm 75 is driven by a solenoid 76, which is operated according to an electric signal supplied from the control apparatus 63. Similarly, a diaphragm 77 is provided in the middle of the passage 72c in the air-switching valve 72, and the passage 72c can be opened and closed by driving the diaphragm 77. The diaphragm 77 is driven by a solenoid 78, which is operated according to an electric signal supplied from the control apparatus 63.

The air change valve 72 is constituted so that, when the same electric signal is input into the solenoids 76 and 78, the diaphragm 75 is driven in a direction to closes the passage 72b and the diaphragm 77 is driven in a direction to open the passage 72c.

Here, the three-way valve SV5 of the supply system is switched to the TiCl₄ supply system when a compressed air is not supplied, and is switched to the NH₃ supply system when a compressed air is supplied. Moreover, the three-way valve EV7 of the exhaust system is switched to the NH₃ exhaust system when a compressed air is not supplied, and is switched to the TiCl₄ exhaust system when a compressed air is supplied.

In the above-mentioned structure, when a compressed air is supplied to the air passage 74 by the air-switching valve 72 (a direction of arrow A of FIG. 14), the three-way valve SV5 of the supply system is switched to the TiCl₄ supply system, and the three-way valve EV7 of the exhaust system is switched to the TiCl₄ exhaust system. This is equivalent to the process shown in FIG. 10 and FIG. 11. Additionally, when a compressed air is supplied to the air passage 73 by the air-switching valve 72 (a direction of arrow B of FIG. 14), the three-way valve SV5 of the supply system is changed to the NH₃ supply system, and the three-way valve EV7 of the exhaust system is changed to the NH₃ exhaust system. This is equivalent to the process shown in FIG. 12 and FIG. 13.

As mentioned above, the three-way valves of the supply system and the exhaust system can be synchronously operated using the air-switching valve 72.

Although the TiN film is produced by TiCl₄ and NH₃ in the above-mentioned embodiment, the following film deposition processes, as other examples, can be efficiently performed using the processing apparatus according to the present invention: deposition of a TiN film by TiF₄ and NH₃; deposition of a TiN film by TiBr₄ and NH₃; deposition of a TiN film by TiI₄ and NH₃; deposition of a TiN film by Ti [N(C₂H₅CH₃)]₄ and NH₃; deposition of a TiN film by Ti [N(CH₃)₂]₄ and NH₃; deposition of a TiN film by Ti[N(C₂H₅)₂]₄ and NH₃; deposition of a TaN film by TaF₅ and NH₃; deposition of a TaN film by TaCl₅ and NH₃; deposition of a TaN film by TaBr₅ and NH₃; deposition of a TaN film by TaI₅ and NH₃; deposition of a TaN film by Ta(NC(CH₃)₃) (N(C₂H5)₂)₃ and NH₃; deposition of a TaN film by Ta(N(CH₃)₂) (NC₅H₁₁) and NH₃; deposition of a TaN film by Ta[N(C₂H₅)₂]₅ and NH₃; deposition of a TaN film by Ta[N(CH₃)₂]₅ and NH₃; deposition of a TaN film by Ta(N(C₂H₅)₂)₃(N(C₂H₅)₂) and NH₃; deposition of a WN film by WF₆ and NH₃; deposition of a Al₂O₃ film by Al(CH₃)₃ and H₂O; deposition of a Al₂O₃ film by Al(CH₃)₃ and H₂O₂; deposition of a ZrO₂ film by Zr(O-t(C₄H₄))₄ and H₂O; deposition of a ZrO₂ film by Zr(O-t(C₄H₄))₄ and H₂O₂; deposition of a Ta₂O₅ film by Ta(OC₂H₅)₅ and H2O; deposition of a Ta₂O₅ film by Ta(OC₂H₅)₅ and H₂O₂; and deposition of a Ta₂O₅ film by Ta(OC₂H₅)₅ and O₂.

As mentioned above, according to the present invention, in the processing apparatus, which forms film deposition by alternately supplying a plurality of source gases, the source gases are prevented from reacting with each other within an exhaust pipe, which prevents the exhaust pipe from clogging due to a by-product. Moreover, source gases exhausted as being unreacted are trapped and returned to a supply system for reuse, which can reduce an amount of consumption of the source gasses.

The present invention is not limited to the specifically disclosed embodiments, and variations and modifications may be made without departing from the scope of the present invention.

The present application is based on Japanese priority application No. 2002-291578, the entire contents of which are hereby incorporated by reference.

1. A processing apparatus for performing a process by supplying alternately a first source gas and a second source gas to a processing substrate, the processing apparatus comprising:
a processing container in which the processing substrate is placed;
a first supply system for supplying said first source gas into the processing container;
a second supply system for supplying said second source gas into the processing container;
a first exhaust system for exhausting said first source gas from an inside of the processing container;
a second exhaust system for exhausting said second source gas from an inside of the processing container;
supply system switching means for switching a gas supply system connected to said processing container between said first supply system and said second supply system;
exhaust system switching means for switching a gas exhaust system of said processing container between said first exhaust system and said second exhaust system;
control means for controlling said supply system switching means and said exhaust system switching means so as to switch the gas exhaust system to said first exhaust system when the gas supply system is switched to said first supply system, and switch the gas exhaust system to said second exhaust system when the gas supply system is switched to said second supply system.

2. The processing apparatus as claimed in claim 1 further comprising:
a trap provided in said first exhaust system so as to trap said first source gas; and
a recovery pipe for returning said first source gas that is trapped by the trap to said first supply system.

3. The processing apparatus as claimed in claim 1 further comprising a trap provided in said second exhaust system so as to trap a reaction by-product produced by a reaction of said first source gas and said second source gas.

4. The processing apparatus as claimed in claim 1 further comprising a third supply system for supplying an inert gas to said processing apparatus.

5. The processing apparatus as claimed in claim 1, wherein said supply system switching system includes a first supply system stop valve provided in said first supply system and a second supply system stop valve provided in said second supply system, and opening and closing of the first supply system stop valve and the second supply system stop valve are controlled by said control means.

6. The processing apparatus as claimed in claim 1, wherein said exhaust system switching system includes a first exhaust system stop valve provided in said first exhaust system and a second exhaust system stop valve provided in said second exhaust system, and opening and closing of the first exhaust system stop valve and the second exhaust system stop valve are controlled by said control means.

7. The processing apparatus as claimed in claim 1, wherein said supply system switching means includes a supply system three-way valve connectable to one of said first supply system and said second supply system; said exhaust system switching means includes an exhaust system three-way valve connectable to one of said first exhaust system and said second exhaust system; and said supply system three-way valve and said exhaust system three-way valve are controlled by said control means.

8. The processing apparatus as claimed in claim 7, wherein said supply system three-way valve and said exhaust system three-way valve are pneumatically operated valves, and a compressed air supplied to the pneumatically operated valves is supplied by an air-switching valve to one of said supply system three-way valve and said exhaust system three-way valve.

9. The processing apparatus as claimed in claim 1, wherein said first source gas is selected from a group consisting of TiCI₄, TiF₄, TiBr₄, TiI₄, Ti[N(C₂H₅CH₃)]₄, Ti[N(CH₃)₂]₄, Ti[N(C₂H₅)₂]₄, TaFa₅, TaCl₅, TaBr₅, TaI₅, Ta(NC(CH₃)₃)(N(C₂H₅)₂)₃, Ta(N(CH₃)₂)₃(NC₅H₁₁), Ta[N(C₂H₅)₂]₅, Ta[N(CH₃)₂]₅ and Ta(N(C₂H₅)₂)₃(N(C₂H₅)₂, and said second source gas is selected from a group consisting of NH₃, N₂H₄, NH(CH₃)₂ and N₂H₃(CH₃), so as to deposit a TiN film or a TaN film on said processing substrate.

10. The processing apparatus as claimed in claim 4, wherein said first source gas is selected from a group consisting of TiCI₄, TiF₄, TiBr₄, TiI₄, Ti[N(C₂H₅CH₃)]₄, Ti[N(CH₃)2]₄, Ti[N(C₂H₅)₂]₄, TaF₅, TaCl₅, TaBr₅, TaI₅, Ta(NC(CH₃)₃)(N(C₂H₅)₂)₃, Ta(N(CH₃)₂)₃(NC₅H₁₁) Ta[N(C₂H₅)₂]₅, Ta[N(CH₃)₂]₅ and Ta(N(C₂H₅)₂)₃(N(C₂H₅)₂), said second source gas is selected from a group consisting of NH₃, N₂H₄, NH(CH₃)₂ and N₂H₃(CH₃), said inert gas is selected from a group consisting of N₂, Ar and He, so as to deposit a TiN film or a TaN film on said processing substrate.
